(19) United States
(12) Patent Application Publication
(10) Pub. No.: US 2007/0146141 A1
(43) Pub. Date: Jun. 28, 2007

(54) Method for authenticating product

(76) Inventors: Lewis Michael Popplewell, Morganville, NJ (US); Clint Dee Winton Brooks, Sea Bright, NJ (US)

Correspondence Address: INTERNATIONAL FLAVORS & FRAGRANCES INC., 521 WEST 57TH ST, NEW YORK, NY, 10019, US

(21) Appl. No.: 11/316,827

(22) Filed: Dec. 22, 2005

(51) Int. Cl. G08B 13/14; H01L 23/28

(52) U.S. Cl. 340/572.8; 257/787

(57) ABSTRACT

Radio frequency identification tags are placed in contact with a product thereby allowing the tags to be read by an appropriate scanning device. Placement of the tags, either conspicuously or inconspicuously within the package allows for the verification that the product is authentic and is not a knock off or grey market good. Methods for verifying the authenticity of the respective items.

### FIELD OF THE INVENTION

The present invention employs radio frequency identification devices to authenticate products and to provide assurance as to the quality and source of the product.

### BACKGROUND OF THE INVENTION

Radio frequency identification devices (“RFID”) are known in the art. There are numerous patents and applications disclosing the use of RFID for managing inventory and pricing of items of the items at time of purchase.

A brief overview of these patents include U.S. Pat. Nos. 5,776,713; 5,984,983; 6,232,124; 6,312,911; 6,458,595; 6,490,030; 6,512,580; 6,638,593; 6,707,539; and 6,796,504.

Despite the disclosures of these applications, there is a continuing need for the development of new technology that can be used to authenticate and verify the source of a product.

### SUMMARY OF THE INVENTION

The present invention provides a radio frequency identification device in physical contact with a product.

In another embodiment of the present invention provides a method for authenticating the source of product through the incorporation of a RFID in intimate contact of a product, and reading the RFID to verify the product is authentic.

These and other variations of the present invention will be become apparent from reading the specification and examples. DETAIL DESCRIPTION OF THE INVENTION

The present invention provides a RFID in intimate contact with the product. Previously the RFID was place on the label on the outside of the packaging or on other suitable placement such as a cap or other pieces of packaging.

In the present invention, the RFID is intentionally placed inside the packaging and is in physical contact with the product. Depending on the desire of the manufacturer the placement of the RFID and the authenification process provides flexibility. For example, the manufacture may desire to provide a visual identification as to the authenticity of the product of the presence of the RFID before the RFID device is read. If a visible RFID approach is employed, the RFID may be active meaning that the tag has a battery or other suitable power source to boost the range of the reader.

Alternatively a more subtle approach maybe employed in that the RFID maybe concealed in some way within the product so that it is not readily visible to the consumer. Numerous methods for doing this is possible including but not limited to the tinting of a bottle, incorporation of the RFID inside a feature of the product such as a dispensing tube or , as well as providing the ability to have the RFID read with a scanner before purchase that indicates that the product is authentic.

Authentic or authentification as used in this application is understood that the product containing the RFID is manufactured by an authorized party and is not counterfeit or a gray market product. The present invention provides a simple, inexpensive and verifiable way to allow a consumer confirm that the product they are purchasing is made by an authorized distributor and is not counterfeit. Since the RFID tag is being used for authentification purposes the manufacturer will employ the ability to control the tag and reader. Historically the original designer of a semiconductor device in the tag determined the parameters in which the reader would be able to communicate with the tag. The use of the appropriate frequencies could make the RFID visible to a limited number of readers which the manufacturer would be aware of. This discrete use of the RFID would make it more difficult for a would be counterfeiter to know of the presence of the RFID, the appropriate frequency for the RFID tag to use so that the scanner would read it and also the information contained in the tag itself.

Further assurance that the article is genuine article and not a copy or counterfeit good could be created by using secondary or tertiary RFID tags in the label, caps or other parts of the packaging. The additional tags can provide the same or different information as the tag that is in contact with the product. Specific tags can be provided to trace the authenticity of the product components thereby allowing the genuine manufacturer to trace the components of the manufacture.

For example using a fine fragrance, the manufacturer could impart tags in the oil as it leaves the factory. Then at the bottling facility the genuine bottles can have tags in the label or in the dispensing mechanism. This would allow the manufacture to determine which component(s) are authentic and to trace the supply chain to determine where the counterfeiting activities were taking place.

In many applications, it is desirable to communicate with a tag when other similar tags are simultaneously visible to the reader. The ability of the tag/ reader system to communicate or read unambiguously with one tag at a time is determined by the anti-collision algorithm used to identify each tag and establish a communication session with the tag.

In a preferred embodiment, the information provided by the RFID tags are encrypted providing yet another level of protection for the data being provided by the tag. The encryption can be resolved through the use of a decoder which would decipher the information provided in the The placement of the RFID in intimate contact with the product contemplates the encapsulation of the RFID with an appropriate material to protect the product from contamination, and to ensure the functionality of the RFID. Suitable encapsulation materials include without limitation glass, vitreous materials, polymeric material such as polyethylene, polyethylene terphthalate and the polymer systems disclosed in U.S. Patent Application 2004-0138093A1, which is commonly assigned to the same assignee as the present application. The encapsulated tags may be made into specific shapes or colors to either help hide the tag or to provide a distinct visual cue.

Another advantage of placing the RFID in contact with the product is that it can be used to deliver additional information such as expiration dates, production lot numbers, site of manufacture and other information that will assist in the tracking of the product through the production channels, as well as making sure the product has not passed its expiration date.

In a highly preferred embodiment of the invention the RFID is provided with a series of different numbers, preferably random that could be used to authenticate the source of the product. The manufacturer would have access to the proper numbers, and along with other information provided either from the product packaging or from the RFID would provide a check for the product authenticity. For example, the RFID made to produce random numbers within a given range of numbers to verify the product. This in addition to markings on the product label could be coordinated to provide a code that would be only known to a manufacturer to determine authenticity. For illustration, a simplistic example is provided below:

A RFID could easily provide six alphanumeric digits of information. A code could be conceived wherein the first digit indicates the location of the plant where the product was made by a letter, the month could be indicated by another letter and the production lot indicated by the remaining 4 digits of the RFID display. These 4 remaining digits could be randomly assigned and only known by the manufacturer. One could investigate and validate the authenticity of a product in the field by use of the appropriate device to read the RFID as well as having knowledge of the appropriate codes.

A further improvement can be made by incorporating the RFID into the product itself. For example the RFID could be incorporated into the product as part of a decorative feature or icon that are used in such items as candles. This approach makes the RFID less noticeable to the consumer, but does not detract from the functional benefit of providing specific information from the RFID.

In another embodiment of the invention, the RFID can remain innocuous by attaching the RFID to an inside wall of the package. Attachment of the RFID to the package wall can be accomplished by any means suitable for the situation including the use of adhesives, lamination of the RFID to the package, pressure fits and the like. The packaging itself would be opaque or constructed that the RFID is not visible to the consumer. Only when the RFID scanning device is employed the information would be detected.

Yet another approach to the present invention would be to employ a tamper resistant mechanism to protect the RFID from being removed or otherwise manipulated without physical evidence to indicate that the product has been opened. The combination of tamper resistant sealing protecting an internal RFID makes it unlikely that counterfeiters will be able to simply add a RFID once they learn of the RFID placement in the packaging.

In yet another embodiment of the present invention, the RFID can not be read without the removal of an outer level of packaging. The outer packaging similar to a box is provided that prevents the RFID from being read. Only after the removal of the outer impermeable packaging will the RFID be readable by an appropriate scanner device.

The products that can be used in connection with the present invention is widely variable. The following products are included for illustration, such as industrial chemicals, photographic chemicals, agriculture chemicals, horticulture and forestry, artificial resins, plastics, fire extinguishing compositions, soldering materials, chemical substances for preserving foodstuffs, tanning substances, adhesives, paints, varnishes, lacquers, rust preventing materials, wood protecting materials, colorants, mold preventing materials, raw natural resins, bleaching preparations, laundry detergents, fabric softeners and other substances for laundry use, cleaning, polishing, scouring and abrasive preparations, soaps, perfumery, essential oils, cosmetics, hair lotions, industrial oils and greases, lubricants, fuels, candles, wicks, pharmaceutical, veterinary and sanitary preparations, dietetic substances adapted for medical and dental use, baby food for babies, dental wax, preparations for destroying vermin, fungicides, herbicides, fungicides, metals, jewellery, stones, horological and chronometric instruments, magnetic data carriers, recording discs, surgical, medical, dental and veterinary apparatus and instruments, artificial limbs, orthopedic articles, suture materials, firearms, ammunition and projectiles, explosives, fireworks, paper, cardboard and goods made from these materials, artists materials, paint brushes, typewriters and office requisites, instructional and teaching materials, plastic materials for packaging, leather and imitation leather goods, building materials, textiles and textile goods, meat, fish, poultry, meat extracts, coffee, teas, cocoa, sugar, rice, tapioca, sago, artificial coffee, agricultural, horticultural and forestry products and grains, beers, mineral and aerated waters and other non-alcoholic drinks, fruit drinks and fruit juices, syrups and other preparations for making beverages, alcoholic beverages and tobacco.

These and additional modifications and improvements of the present invention may also be apparent to those with ordinary skill in the art. The particular combinations of element described and illustrated herein are intended only to represent only a certain embodiment of the present inventions and is not intended to serve as limitations of alternative articles with the spirit and scope of the invention.

### EXAMPLE I

RFID tags encapsulated in glass were obtained from AVID Identification Systems Inc., Norco, Calif. along with a Scanner that can read the tag identification number.

The tags were placed in a representative perfume composed of 11% fragrance oil, 80% ethanol, and 9% water. The container used was glass, had a spray dispenser in place, and had a volume of approximately 1 ounce.

Immediately after being placed in the perfume, and after storage in the perfume after 23 days storage at ambient temperature, the scanner was able to read the tag correctly. This indicated that the RFID survived functionally after immersion in the product.

We claim:

1. A method for authenticating the source of a product through the incorporation of a RFID in intimate contact of a product.

2. A method as in claim 1, wherein the RFID is encapsulated within the product.

3. A method as in claim 2, wherein the encapsulation materials are selected from the group consisting of glass, vitreous materials, polyethylene and polyethylene terphthalate.

4. A method as in claim 3, wherein the encapsulation materials are made into specific shapes or colors.

5. A method as in claim 1, wherein the is provided with the set of random numbers to authenticate the source of a product.

6. A method as in claim 1, wherein the RFID is incorporated into a product.

7. A method as in claim 1, wherein the RFID is attached to the inside wall of the package.

8. A method as in claim 1, wherein the RFID is protected by a tamper resistant mechanism.

9. A method as in claim 1, wherein the RFID cannot be read without the removal of an outer level of packaging of a product.
